(19) United States
(12) Patent Application Publication
(10) Pub. No.: US 2020/0403512 A1
(43) Pub. Date: Dec. 24, 2020

(54) CONTROL CIRCUIT MODULE, ELECTRONIC COMPONENT CONNECTION STRUCTURE, AND POWER CONVERSION DEVICE

(71) Applicant: Murata Manufacturing Co., Ltd., Nagaokakyo-shi (JP)

(72) Inventors: Takayuki TANGE, Nagaokakyo-shi (JP); Munetake MIYASHITA, Nagaokakyo-shi (JP); Yuji TAMURA, Nagaokakyo-shi (JP); Tatsuya YOSHINAKA, Nagaokakyo-shi (JP); Hideaki HASHI, Nagaokakyo-shi (JP)

(21) Appl. No.: 17/009,809

(22) Filed: Sep. 2, 2020

Related U.S. Application Data
(63) Continuation of application No. PCT/JP2019/000165, filed on Jan. 8, 2019.

(30) Foreign Application Priority Data
Mar. 19, 2018 (JP) 2018-050332

(51) Int. Cl. H02M 3/158; G05F 1/59; H05K 1/18

(52) U.S. Cl. CPC H02M 3/158; H05K 1/181; G05F 1/59

(57) ABSTRACT

A control circuit module includes FETs each including a control terminal, an input terminal, and an output terminal, a control circuit connected to the control terminals and controlling on/off operations of the FETs by outputting a control signal to the control terminals, a first package including the FETs and the control circuit provided therein and including a first surface, a second surface, and a third surface, which is a side surface perpendicular or substantially perpendicular to the first surface and the second surface, first electrodes provided in the first package and exposed from the first surface of the first package, and a second electrode that is provided in the first package and exposed from the second surface of the first package.

### CROSS REFERENCE TO RELATED APPLICATIONS

This application claims the benefit of priority to Japanese Patent Application No. 2018-050332 filed on Mar. 19, 2018 and is a Continuation Application of PCT Application No. PCT/JP2019/000165 filed on Jan. 8, 2019. The entire contents of each application are hereby incorporated herein by reference.

### BACKGROUND OF THE INVENTION

### 1. Field of the Invention

The present invention relates to a control circuit module, an electronic component connection structure, and a power conversion device.

### 2. Description of the Related Art

A DC-DC converter has been proposed that includes an LC module, a control IC, and a mounting substrate on which the LC module and the control IC are mounted (for example, refer to Japanese Unexamined Patent Application Publication No. 2013-005578). In this case, the LC module is formed by mounting an inductor having a choke coil formed therein on a capacitor array having a plurality of capacitors formed therein and integrating the inductor with the capacitor array. The control IC includes a switching element, such as an FET. In the DC-DC converter, the LC module and the control IC are mounted at positions on a mounting substrate that do not overlap in the thickness direction of the mounting substrate and the inductor and the control IC are electrically connected to each other via a wiring line portion of the mounting substrate.

However, in the DC-DC converter disclosed in Japanese Unexamined Patent Application Publication No. 2013-005578, since the inductor and the control IC are electrically connected to each other via the wiring line portion of the mounting substrate, a parasitic inductance generated by the wiring line portion may affect the operation of the DC-DC converter. In particular, as the length of the wiring line portion interposed between the inductor and the control IC increases, the parasitic inductance will increase by a corresponding amount and may be a factor in reducing the power conversion efficiency of the DC-DC converter.

### SUMMARY OF THE INVENTION

Preferred embodiments of the present invention provide control circuit modules, electronic component connection structures, and power conversion devices that are each able to reduce or prevent degradation of power conversion efficiency.

A preferred embodiment of the present invention provides a control circuit module that includes a first switching element including a control terminal and two input/output terminals; a control circuit that is connected to the control terminal and controls operation of the first switching element by outputting a control signal to the control terminal; a package that includes the first switching element and the control circuit therein and that includes a first surface that faces in a first direction, a second surface that faces in a second direction that is opposite the first direction, and a third surface that intersects the first surface and the second surface; a first electrode that is electrically connected to either one of the two input/output terminals and that is provided in the package so as to be at least partially exposed from the first surface of the package; and a second electrode that is electrically connected to the other one of the two input/output terminals and is provided in the package so as to be at least partially exposed from the second surface or the third surface of the package.

In addition, a control circuit module according to a preferred embodiment of the present invention may further include a second switching element including a control terminal and two input/output terminals, and the second electrode may be electrically connected to a connection point between the input/output terminals of first switching element and the second switching element.

A preferred embodiment of the present invention provides a power conversion device that includes a control circuit module according to a preferred embodiment of the present invention; and an inductor element including a coil and two lead frames that are electrically connected to both ends of the coil; and in which either one of the two lead frames contacts the second electrode.

In addition, in a power conversion device according to a preferred embodiment of the present invention, the second electrode may be provided on the second surface and the second electrode and either one of the two lead frames may overlap when viewed in a direction perpendicular or substantially perpendicular to the surface where the second electrode is provided and be connected to each other.

A preferred embodiment of the present invention provides an electronic component connection structure that includes a first electronic component that includes a switching element including a control terminal and two input/output terminals, a first package that includes the switching element therein and that includes a first surface that faces in a first direction, a second surface that faces in a second direction that is opposite the first direction, and a third surface that intersects the first surface and the second surface, a first electrode that is electrically connected to either one of the two input/output terminals and that is provided in the first package so as to be at least partially exposed from the first surface of the first package, and a second electrode that is electrically connected to the other one of the two input/output terminals and is provided in the first package so as to be at least partially exposed from the second surface or the third surface of the first package; and a second electronic component that includes a second package and a third electrode that at least partially exposed at an outer surface of the second package.

The second electrode and the third electrode overlap when viewed in a direction perpendicular or substantially perpendicular to the surface where the second electrode is provided and are connected to each other.

In addition, in an electronic component connection structure according to a preferred embodiment of the present invention, the first package and the second package may be arranged so as to at least partially overlap when viewed in a direction perpendicular or substantially perpendicular to the surface where the second electrode is provided.

According to a preferred embodiment of the present invention, the first electrode is electrically connected to either one of the two input/output terminals of the switching element and is provided in the package so as to be at least partially exposed from the first surface of the package. In addition, the second electrode is electrically connected to the other one of the two input/output terminals of the switching element and is provided in the package so as to be at least partially exposed from the second surface or the third surface of the package. Thus, for example, when a power conversion device is provided by combining a control circuit module according to a preferred embodiment of the present invention with an inductor element that includes a coil and lead frames that are connected to the coil, a lead frame of the inductor element can be directly connected to the second electrode. Therefore, there is no need to connect an input/output terminal of the switching element and the lead frame to each other via, for example, a conductor pattern provided on a substrate on which the inductor element and the control circuit module are mounted. Therefore, a parasitic inductance generated by a wiring line portion between the inductor element and the switching element is able to be reduced, and therefore, degradation of the power conversion efficiency of the power conversion device is able to be reduced or prevented.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a perspective view of a portion of a power conversion device according to a preferred embodiment of the present invention.

FIG. 2A is a side view of a portion of a portion of a power conversion device according to a preferred embodiment of the present invention.

FIG. 2B is a plan view of a portion of a portion of a power conversion device according to a preferred embodiment of the present invention.

FIG. 3A is a circuit diagram illustrating a case where a power conversion device according to a preferred embodiment of the present invention is configured to operate as a step-down DC-DC converter.

FIG. 3B is a circuit diagram illustrating a case where a power conversion device according to a preferred embodiment of the present invention is configured to operate as a step-up DC-DC converter.

### DETAILED DESCRIPTION OF THE PREFERRED EMBODIMENTS

Hereafter, preferred embodiments of the present invention will be described in detail while referring to the drawings. A power conversion device according to a preferred embodiment of the present invention includes an inductor element including a lead frame and a control circuit module including two switching elements and a control circuit. The control circuit module includes a package including a first surface that faces a substrate and a second surface that faces the opposite side from the substrate when the control circuit module is mounted on the substrate, a first electrode that is provided in the package so as to be exposed from the first surface of the package, and a second electrode that is commonly connected to one input/output terminal of each of the two switching elements and is exposed from the second surface of the package. The lead frame of the inductor element contacts the second electrode of the control circuit module. As a result of the power conversion device according to the present preferred embodiment having this structure, the wiring line distance between the inductor element and the switching elements is shortened.

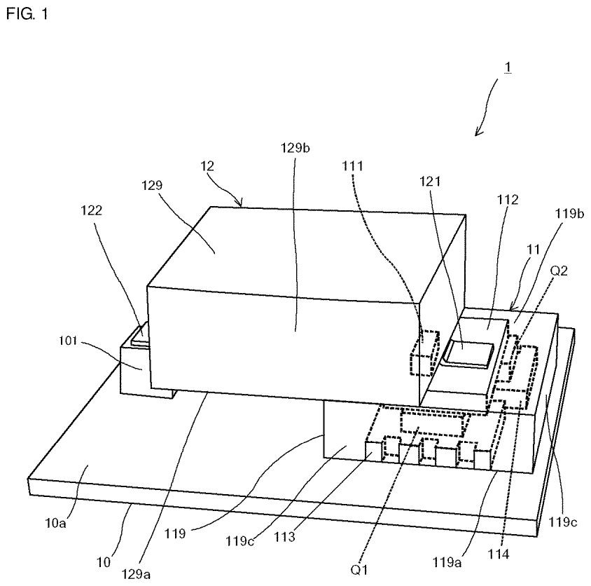

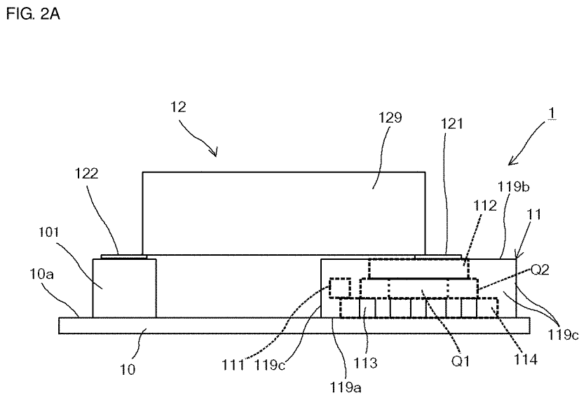

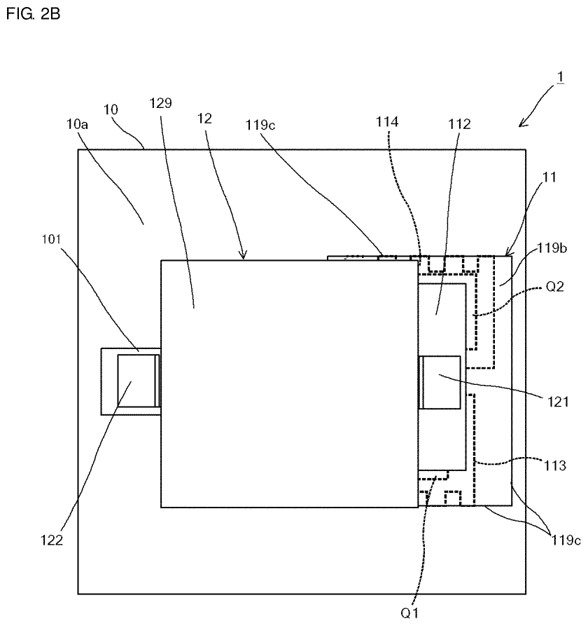

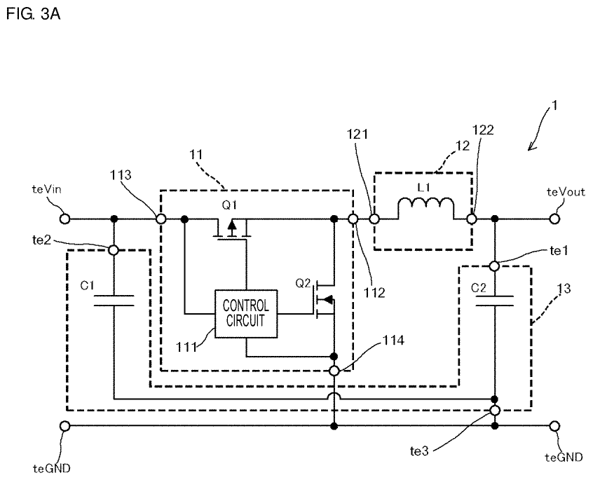

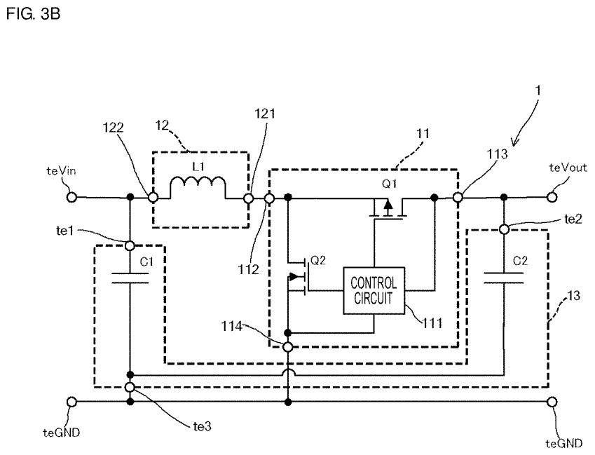

As illustrated in FIGS. 1, 2A, and 2B, a power conversion device 1 according to a preferred embodiment of the present invention includes a substrate 10, a control circuit module 11, which is a first electronic component, that is mounted on the substrate 10, and an inductor element 12, which is a second electronic component. In addition, as illustrated in FIGS. 3A and 3B, the power conversion device 1 includes a capacitor array 13 that includes two capacitors C1 and C2. Note that illustration of the capacitor array 13 is omitted from FIGS. 1, 2A, and 2B. The power conversion device 1 operates as a step-down DC-DC converter as illustrated in FIG. 3A or a step-up DC-DC converter as illustrated in FIG. 3B. In the case where the power conversion device 1 operates as a step-down DC-DC converter, as illustrated in FIG. 3A, one end of a coil L1 of the inductor element 12 is connected to an output terminal teVout and the other end of the coil L1 is connected to the control circuit module 11. On the other hand, in the case where the power conversion device 1 operates as a step-up DC-DC converter, as illustrated in FIG. 3B, one end of the coil L1 of the inductor element 12 is connected to an input terminal teVin and the other end of the coil L1 is connected to the control circuit module 11. Note that, in FIGS. 3A and 3B, a ground terminal teGND is maintained at a ground potential.

Returning to FIGS. 1, 2A, and 2B, the substrate 10 includes a conductor pattern (not illustrated) provided thereon that defines a portion of the DC-DC converter and a pin 101 that is electrically connected to the capacitor array 13 (not illustrated in FIGS. 1, 2A, and 2B). Furthermore, in addition to the pin 101, the substrate 10 is provided with a pin (not illustrated) that is electrically connected via a conductor pattern to a first electrode 114 of the control circuit module 11, which is described later, and a pin (not illustrated) that is electrically connected via a conductor pattern to a first electrode 113 of the control circuit module 11, which is described later. Note that the materials of the conductor patterns and pins (for example, pin 101) may be any of various metals.

As illustrated in FIGS. 3A and 3B, the capacitor array includes three terminal electrodes te1, te2, and te3. In addition, the capacitor array 13 includes a package that has, for example, a flat shape, that includes the two capacitors C1 and C2 provided therein, and that is mounted on the substrate 10 with one surface thereof in the thickness direction facing a main surface 10a of the substrate 10 illustrated in FIGS. 1, 2A, and 2B. The three terminal electrodes te1, te2, and te3 are provided at three locations on the side surfaces of the package. The terminal electrodes te1 and te2 are respectively electrically connected to first ends of the capacitors C1 and C2 and the terminal electrode te3 is electrically connected to second ends of the two capacitors C1 and C2. The terminal electrode te1 contacts the pin 101 provided on the substrate 10 in the state in which the capacitor array 13 is mounted on the substrate 10 illustrated in FIGS. 1, 2A, and 2B. In addition, the terminal electrode te2 contacts the pin that is electrically connected to the first electrode 113 and the terminal electrode te3 contacts the pin that is electrically connected to the first electrode 114.

As illustrated in FIGS. 1, 2A, and 2B, the inductor element 12 includes the coil L1 (refer to FIGS. 3A and 3B), a second package 129 that includes the coil L1 provided therein, and lead frames 121 and 122, which are two third electrodes that are electrically connected to the two ends of the coil L1. The second package 129 has a flat rectangular or substantially rectangular parallelepiped shape in a plan view and is arranged so as to be at a prescribed distance from the substrate 10 with one main surface 129a thereof in the thickness direction facing the main surface 10a of the substrate 10. The lead frames 121 and 122 are respectively provided at two locations on side surfaces 129b of the second package 129.

The control circuit module 11 includes two FETs Q1 and Q2, a control circuit 111 that controls on/off operations of the FETs Q1 and Q2, a first package 119 inside of which the FETs Q1 and Q2 and the control circuit 111 are provided, the two first electrodes 113 and 114, and the second electrode 112.

The FETs Q1 and Q2 are preferably, for example, MOSFETs. The FETs Q1 and Q2 each include a gate terminal, which is a control terminal, and source and drain terminals, which are input/output terminals. As illustrated in FIGS. 3A and 3B, the source terminal of the FET Q1 and the drain terminal of the FET Q2 are connected to each other. The control circuit 111 is connected to the gate terminals of the FETs Q1 and Q2 and controls on/off operations of the FETs Q1 and Q2 by outputting a control signal to these gate terminals. The control circuit 111 receives power from the first electrode 113. For example, bare chips, such as large scale integration (LSI) chips, using compound semiconductor materials such as gallium arsenide (GaAs) and gallium nitride (GaN) in addition to silicon (Si) can be used as switching elements.

As illustrated in FIGS. 1, 2A, and 2B, the first package 119 has a flat rectangular or substantially rectangular parallelepiped shape and includes a first surface 119a, which is one surface thereof in the thickness direction, a second surface 119b, which is the other surface thereof in the thickness direction, and four third surfaces 119c, which are side surfaces. When the first package 119 is mounted on the substrate 10, the first surface 119a faces the substrate 10 (first direction side) and the second surface 119b faces toward the opposite side (second direction side) from the substrate 10. The four third surfaces 119c intersect the first surface 119a and the second surface 119b. The material of the first package 119 is preferably, for example, a non-electrically conductive resin material and is, for example, manufactured using a molding technique.

The two first electrodes 113 and 114 each have a flat plate shape, for example, and are provided in the first package 119 so that one surface thereof in the thickness direction is exposed from the first surface 119a of the first package 119. The second electrode 112 has a flat plate shape, for example, and is provided in the first package 119 so that one surface thereof in the thickness direction is exposed from the second surface 119b of the first package 119. The materials of the two first electrodes 113 and 114 and the second electrode 112 are a metal. In addition, as illustrated in FIGS. 3A and 3B, the first electrode 113 is electrically connected to the drain terminal of the FET Q1 and the first electrode 114 is electrically connected to the source terminal of the FET Q2. The second electrode 112 is connected to both the source terminal of the FET Q1 and the drain terminal of the FET Q2.

As illustrated in FIG. 2B, in the power conversion device according to the present preferred embodiment, the second electrode 112 of the control circuit module 11 and the lead frame 121 of the inductor element 12 overlap when viewed in a direction perpendicular or substantially perpendicular to the second surface 119b of the first package 119 where the second electrode 112 is provided and the lead frame 121 contacts the second electrode 112. In addition, when viewed in the direction perpendicular or substantially perpendicular to the second surface 119b where the second electrode 112 is provided, the first package 119 and the second package 129 partially overlap each other. As a result of this structure, the wiring line distance between the inductor element 12 and the FETs Q1 and Q2 is shortened.

As described above, in the power conversion device 1 according to the present preferred embodiment, the first electrode 113 of the control circuit module 11 is electrically connected to the drain terminal of the FET Q1 and the first electrode 114 is electrically connected to the source terminal of the FET Q2. The first electrodes 113 and 114 are provided in the first package 119 so as to be exposed from the first surface 119a of the first package 119. In addition, the second electrode 112 is electrically connected to a connection point between the source terminal of the FET Q1 and the drain terminal of the FET Q2. The second electrode 112 is provided in the first package 119 so as to be exposed from the second surface 119b of the first package 119. Thus, since the lead frame 121 of the inductor element 12 can be directly connected to the second electrode 112, there is no need for the source terminal of the FET Q1 and the drain terminal of the FET Q2 and the lead frame 121 to be connected to each other via a conductor pattern provided on the substrate 10. Therefore, a parasitic inductance generated by a wiring line portion between the inductor element 12 and the FETs Q1 and Q2 can be reduced, and therefore, degradation of the power conversion efficiency of the power conversion device 1 can be reduced or prevented. Furthermore, generation of noise arising from the parasitic inductance can also be reduced or prevented.

Furthermore, in the power conversion device 1 according to the present preferred embodiment, the control circuit module 11 includes the second electrode 112 that is provided in the first package 119 so as to be exposed from the second surface 119b of the first package 119. In addition, the control circuit module 11 includes the one first package 119 inside of which the two FETs Q1 and Q2 and the control circuit 111 are provided. Thus, the control circuit module 11 and the inductor element 12 are easily arranged on the substrate 10 in a three-dimensional manner and the power conversion device 1 can be reduced in size.

Furthermore, in the power conversion device 1 according to the present preferred embodiment, the second electrode 112 of the control circuit module 11 and the lead frame 121 of the inductor element 12 are connected to each other at portions thereof that overlap when viewed in the direction perpendicular or substantially perpendicular to the second surface 119b where the second electrode 112 of the first package 119 is provided. The lead frame 121 of the inductor element 12 contacts the second electrode 112. Thus, the wiring line distance between the source terminal of the FET Q1 and the drain terminal of the FET Q2 and the lead frame 121 can be shortened. Therefore, since the wiring line distance between the source terminal of the FET Q1 and the drain terminal of the FET Q2 and the lead frame 121 can be shortened, power loss due to this wiring line portion can be reduced by a corresponding amount.

A preferred embodiment of the present invention has been described above, but the present invention is not limited to the configuration of the above-described preferred embodiment. For example, the second electrode 112 of the control circuit module 11 may be provided in the first package 119 so that one surface thereof in the thickness direction is exposed from any one of the four third surfaces 119c, which are the side surfaces of the first package 119. In this case, it is sufficient that the inductor element 12 is mounted on the substrate 10 with the lead frame 121 thereof contacting the second electrode 112 from the third surface 119c side of the first package 119 where the second electrode 112 is exposed.

In the present preferred embodiment, an example has been described in which the control circuit module 11 includes one first package 119 inside of which the two FETs Q1 and Q2 and the control circuit 111 are provided. However, the control circuit module is not limited to this configuration, and for example, the control circuit module may include either one of the two FETs Q1 and Q2 and the control circuit 111. In this case, the FET that is not included in the control circuit module of the two FETs Q1 and Q2 may be mounted on the substrate 10 by itself.

In the present preferred embodiment, an example of the power conversion device 1 that includes the control circuit module 11, which includes two FETs Q1 and Q2, and the inductor element 12 has been described, but the present invention is not limited to this configuration, and for example, may be a device provided with a circuit having another function in which an inductor element or capacitor is connected to a high-potential-side second electrode to which a plurality of FETs are commonly connected. Furthermore, other types of switching elements such as, for example, bipolar transistors may be used instead of the FETs Q1 and Q2.

Preferred embodiments and modifications of the present invention have been described above, but the present invention is not limited to the above-described preferred embodiments and modifications. The present invention includes preferred embodiments obtained by combining the above-described preferred embodiments and modifications as appropriate with appropriate changes made thereto.

Preferred embodiments of the present invention are suitable for use as a DC-DC converter.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A control circuit module comprising:
a first switching element including a control terminal and two input/output terminals;
a control circuit connected to the control terminal and controlling operation of the first switching element by outputting a control signal to the control terminal;
a package including the first switching element and the control circuit provided therein and including a first surface that faces in a first direction, a second surface that faces in a second direction opposite to the first direction, and a third surface that intersects the first surface and the second surface;
a first electrode electrically connected to one of the two input/output terminals and provided in the package so as to be at least partially exposed from the first surface of the package; and
a second electrode electrically connected to another one of the two input/output terminals and provided in the package so as to be at least partially exposed from the second surface or the third surface of the package.

2. The control circuit module according to claim 1, further comprising:
a second switching element including a control terminal and two input/output terminals; wherein
the second electrode is electrically connected to a connection point between the two input/output terminals of first switching element and the second switching element.

3. The control circuit module according to claim 1, wherein the first switching element is a FET.

4. The control circuit module according to claim 2, wherein the second switching element is a FET.

5. The control circuit module according to claim 2, wherein the second switching element is provided in the package.

6. The control circuit module according to claim 1, wherein the first switching element is a MOSFET.

7. The control circuit module according to claim 2, wherein the second switching element is a MOSFET.

8. The control circuit module according to claim 1, wherein the package is made of a non-electrically conductive resin material.

9. A power conversion device comprising:
the control circuit module according to claim 1; and
an inductor element including a coil and two lead frames electrically connected to both ends of the coil; wherein
one of the two lead frames contacts the second electrode.

10. The power conversion device according to claim 9, wherein the second electrode is provided on the second surface and the second electrode and one of the two lead frames overlap when viewed in a direction perpendicular or substantially perpendicular to the surface where the second electrode is provided and are connected to each other.

11. The power conversion device according to claim 9, further comprising:
a second switching element including a control terminal and two input/output terminals; wherein
the second electrode is electrically connected to a connection point between the two input/output terminals of the first switching element and the second switching element.

12. The power conversion device according to claim 9, wherein the first switching element is a FET.

13. The power conversion device according to claim 11, wherein the second switching element is a FET.

14. The power conversion device according to claim 11, wherein the second switching element is provided in the package.

15. The power conversion device according to claim 9, wherein the first switching element is a MOSFET.

16. The power conversion device according to claim 11, wherein the second switching element is a MOSFET.

17. The power conversion device according to claim 9, wherein the package is made of a non-electrically conductive resin material.

18. An electronic component connection structure comprising:
a first electronic component including a switching element including a control terminal and two input/output terminals, a first package including the switching element provided therein and including a first surface that faces in a first direction, a second surface that faces in a second direction that is opposite the first direction, and a third surface that intersects the first surface and the second surface, a first electrode electrically connected to one of the two input/output terminals and provided in the first package so as to be at least partially exposed from the first surface of the first package, and a second electrode electrically connected to another one of the two input/output terminals and provided in the first package so as to be at least partially exposed from the second surface or the third surface of the first package; and
a second electronic component including a second package and a third electrode at least partially exposed at an outer surface of the second package; wherein
the second electrode and the third electrode overlap when viewed in a direction perpendicular or substantially perpendicular to the surface at which the second electrode is provided and are connected to each other.

19. The electronic component connection structure according to claim 18, wherein the first package and the second package at least partially overlap when viewed in the direction perpendicular or substantially perpendicular to the surface where the second electrode is provided.
